(19) United States
(12) Patent Application Publication
(10) Pub. No.: US 2008/0180283 A1
(43) Pub. Date: Jul. 31, 2008

(54) SYSTEM AND METHOD OF CROSS MEDIA INPUT FOR CHINESE CHARACTER INPUT IN ELECTRONIC EQUIPMENT

(75) Inventor: Magnus Nordenhake, Malmo (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 11/669,295

(22) Filed: Jan. 31, 2007

(51) Int. Cl. H03M 11/00

(52) U.S. Cl. 341/22

(57) ABSTRACT

Disclosed is a system and method for inputting Chinese characters and phrases in electronic equipment, such as, for example, portable communications devices. A cross media bar is provided wherein a user selects an alphanumeric character based on a pronunciation of a Chinese character (e.g., Pinyin method of Chinese text enter) that the user desires to input into the electronic equipment. The candidate characters associated with the selected character are displayed in a first format (e.g. a substantially horizontal format) on a display of the electronic equipment. The user is then able to select at least one candidate Chinese character that corresponds to the selected pronunciation. The candidate Chinese characters are displayed to the user in a second format (e.g., a substantially vertical format) on the display. The candidate Chinese characters extend across the portion of the display presenting the candidate characters.

### TECHNICAL FIELD OF THE INVENTION

This invention relates generally to text entry technology. More particularly, aspects of the present invention relate to a system and method for inputting Chinese characters and phrases in electronic equipment, such as, for example, portable communications devices.

### DESCRIPTION OF THE RELATED ART

For many years, keyboard size has been a major size limiting factor in efforts to design and manufacture small portable communications devices. The primary reason for this is if standard typewriter-size keys are used, a portable communications device must be at least as large as the keyboard. Although many kinds of miniaturized keyboards have been used in portable communications devices, they are generally too small to be easily or quickly manipulated by a user.

Incorporating a full-size keyboard in a portable communications device also hinders portable use of the device. Manufacturers have attempted to address this problem in a variety of ways. By incorporating handwriting recognition software in the device, users may directly enter text by writing on a touch-sensitive panel or screen using a stylus. The handwritten text is then converted by recognition software into digital data. Another common approach is a text input method referred to as “multi-tap”. Using multi-tap, a key is pressed multiple times to access the list of letters on that key. For instance, pressing the “2” key once displays an, “a”, twice displays a “b” and three times displays a “c”. To enter two successive letters that are on the same key, the user must either pause or hit a “next” button. Multi-tap is easy to understand, and can be used without any visual feedback (i.e., the user can type (by pressing an alphanumeric keypad) without looking at the electronic equipment display). However, multi-tap is not very efficient and is considered a hindrance by many users of electronic equipment.

Such techniques are typically very inefficient and generally lack speed and accuracy desired by users. These problems are compounded when used with the Chinese language. The Pinyin input method is one of the most commonly used Chinese character input methods that is based on Pinyin, the official system of sounds forming syllables for Chinese language, which was introduced in 1958 by the People's Republic of China. Pinyin is supplementary to the 5,000-year-old traditional Chinese writing system. Pinyin is used in many different ways. For example, it is used as a pronunciation tool for language learners, it is used in index systems, and it is used for inputting Chinese characters into a computer. The Pinyin system adopts the standard Latin alphabets and takes the traditional Chinese analysis of the Chinese syllable into initials, finals (ending sounds) and tones.

Mandarin Chinese has consonant sounds that are found in most modern languages. For example, b, p, m, f, d, t, n, i, g, k, h are quite close to their English equivalents. Other initial sounds, such as retroflex sounds zh, ch, sh and r, palatal sounds j, q and x, as well as dental sounds z, c and s, are different from the common English or Latin pronunciation. Each Pinyin pronunciation generally has one of the five tones (four pitched tones and a “toneless” tone). One of ordinary skill in the art will readily appreciate and understand the initial sounds, final sounds and/or tones used in Pinyin. Accordingly, a detailed listing of Pinyin sounds and/or tones is not duplicated herein.

A common method for inputting Chinese characters is generally referred to the “five-stroke” input method. Five-stroke is generally considered a shape-based input method that is based on the structure, or shape, of characters rather than on their pronunciation. The main concept behind five-stroke input method is that characters can be built by combining roots. Five-stroke method allots approximately 200 radicals, or roots, to five sections corresponding to five types of character strokes in the Chinese writing system: lateral, vertical, left sweep, dot/right sweep and bend. The five-stroke input method divides the set of roots and the keyboard into five main categories according to the shape of the first stroke used to write each character. Each of the five roots is further divided into five levels. The resulting 25 root categories are assigned to the 25 keys A-Y on the keyboard. Typically, the user needs no more than four keystrokes to enter any character in the code chart, and the most frequently used 600 characters require only one or two keystrokes. One drawback associated with the five-stroke method is that the user must know which radicals are assigned to each key, but once the array is known, the user can type quickly and accurately.

### SUMMARY

In view of the aforementioned shortcomings associated with Chinese text entry in portable communications equipment, there is a strong need in the art for an efficient method for inputting Chinese characters on a portable communications device having a reduced keyboard using an intuitive graphical user interface.

According to an aspect of the invention, a method for inputting Chinese characters in electronic equipment, the method comprising: receiving an input signal from an input device, wherein the input signal corresponds to one or more alphanumeric characters selected by an associated user, wherein the input signal corresponds to a pronunciation of a of Chinese character that the associated user desires to input into the electronic equipment; displaying one or more candidate characters associated with the received input signal in a first format on a display, wherein the candidate characters correspond to one or more combinations of pronunciations associated with the received input signal; selecting at least one candidate character based at least in part on the pronunciation of a desired Chinese character to be entered into the electronic equipment; and displaying at least one Chinese character associated with the at least one candidate character, wherein the at least one Chinese character is displayed in a second format on the display and the second format extends across the characters displayed in the first format.

Another aspect of the invention relates to the first format being substantially perpendicular to the second format.

Another aspect of the invention relates to the first format being substantially horizontal and the second format being substantially vertical.

Another aspect of the invention relates to at least one Chinese character being displayed above the selected candidate character and at least one Chinese character is displayed below the selected candidate character.

Another aspect of the invention relates to at least one Chinese character being displayed adjacent the selected candidate character and at least one Chinese character is displayed on an opposing side of the selected candidate character.

Another aspect of the invention relates to the input device being an alphanumeric keypad.

Another aspect of the invention relates to a navigation tool being used to perform the step of selecting at least one candidate character.

Another aspect of the invention relates to selecting at least one of the displayed Chinese characters.

Another aspect of the invention relates to a navigation tool being used by the associated user to perform the step of selecting at least one of the displayed Chinese characters.

Another aspect of the invention relates to the navigation tool being used by the associated user to vertically traverse a listing of Chinese characters to select the at least one Chinese character desired by the user.

Another aspect of the invention relates to the selected Chinese character being displayed on the display as a portion of a message to be conveyed to another associated user over a telecommunications network.

Another aspect of the invention relates to displaying the one or more candidate characters to the associated user in a predetermined manner.

Another aspect of the invention relates to the predetermined manner is based upon a probability that at least one of the candidate characters are most likely to be selected by an associated user.

Another aspect of the invention relates to displaying the at least one Chinese character associated with the at least one candidate character in a predetermined manner.

Another aspect of the invention relates to the predetermined manner being based upon a probability that at least one of the candidate characters are most likely to be selected by an associated user.

According to an aspect of the invention, a portable communications device comprising: a memory; an input device for allowing an associated user to enter user information; a processor that executes an application program within the memory, the application program when executed causing the portable communications device to: receive information from the input device, wherein the information corresponds a plurality of alphanumeric characters corresponding to a pronunciation of a of Chinese character that the associated user desires to input into the portable communications device; displaying one or more candidate characters associated with the received information in a first format on a display, wherein the candidate characters correspond to one or more combinations of pronunciations associated with the received information; selecting at least one candidate character based at least in part on the pronunciation of a desired Chinese character to be entered into the portable communications device; displaying at least one Chinese character associated with the at least one candidate character, wherein the at least one Chinese character is displayed in a second format on the display and the second format extends across the characters displayed in the first format.

Another aspect of the invention relates to the first format being substantially perpendicular to the second format.

Another aspect of the invention relates to the first format being substantially horizontal and the second format being substantially vertical.

Another aspect of the invention relates to the input device being an alphanumeric keypad.

Another aspect of the invention relates to a navigation tool is used by the associated user to select the at least one candidate character.

Another aspect of the invention relates to the navigation tool being used by the associated user to vertically traverse a listing of Chinese characters to select the at least one Chinese character associated with the selected candidate character.

Another aspect of the invention relates to the selected Chinese character being presented on the display in a user-sensible format.

Another aspect of the invention relates to the selected Chinese character being a portion of a message to be electronically conveyed to a user over a telecommunications network.

Another aspect of the invention relates to displaying the one or more candidate characters to the associated user in a predetermined manner.

Another aspect of the invention relates to the predetermined manner is based upon a probability that at least one of the candidate characters are most likely to be selected by an associated user.

Another aspect of the invention relates to a computer program stored on a machine readable medium, the program being suitable for inputting Chinese characters in electronic equipment, wherein: when the program is loaded in memory in the electronic equipment and executed causes the electronic equipment to receive information from an input device, wherein the information corresponds a plurality of alphanumeric characters corresponding to a pronunciation of a of Chinese character that the associated user desires to input into the portable communications device; display one or more candidate characters associated with the received information in a first format on a display, wherein the candidate characters correspond to one or more combinations of pronunciations associated with the received information; select at least one candidate character based at least in part on the pronunciation of a desired Chinese character to be entered into the portable communications device; and display at least one Chinese character associated with the at least one candidate character, wherein the at least one Chinese character is displayed in a second format on the display and the second format extends across the characters displayed in the first format.

Other systems, devices, methods, features, and advantages of the present invention will be or become apparent to one having ordinary skill in the art upon examination of the following drawings and detailed description. It is intended that all such additional systems, methods, features, and advantages be included within this description, be within the scope of the present invention, and be protected by the accompanying claims.

It should be emphasized that the term “comprise/comprising” when used in this specification is taken to specify the presence of stated features, integers, steps or components but does not preclude the presence or addition of one or more other features, integers, steps, components or groups thereof.”

The term “electronic equipment” includes portable radio communication equipment. The term “portable radio communication equipment”, which herein after is referred to as a mobile radio terminal, includes all equipment such as mobile telephones, pagers, communicators, i.e., electronic organizers, personal digital assistants (PDA's), portable communication apparatus, smart phones or the like.

### BRIEF DESCRIPTION OF THE DRAWINGS

The foregoing and other embodiments of the invention are hereinafter discussed with reference to the drawings. The components in the drawings are not necessarily to scale, emphasis instead being placed upon clearly illustrating the principles of the present invention. Likewise, elements and features depicted in one drawing may be combined with elements and features depicted in additional drawings. Moreover, in the drawings, like reference numerals designate corresponding parts throughout the several views.

FIGS. 1 and 2 are exemplary schematic diagrams illustrating electronic equipment in accordance with aspects of the present invention.

FIG. 3 is an exemplary user input device in accordance with aspects of the present invention.

FIGS. 4-10 are exemplary graphical user interfaces in accordance with aspects of the present invention.

FIG. 11 is an exemplary method in accordance with aspects of the present invention.

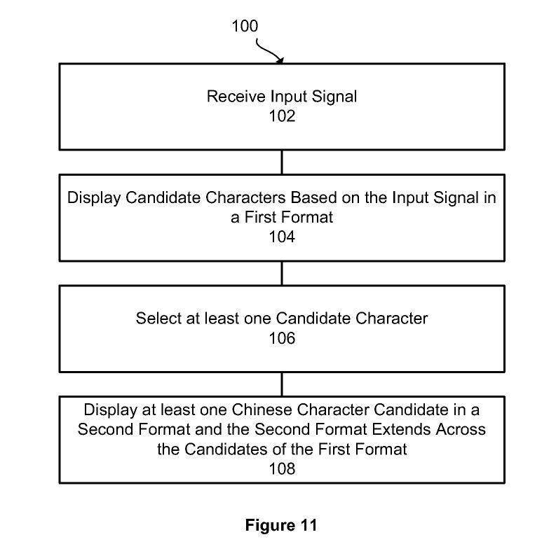

### DETAILED DESCRIPTION OF EMBODIMENTS

Aspects of the present invention relate to a system and method for inputting Chinese characters and phrases in electronic equipment, such as, for example, portable communications devices. A cross media bar is provided wherein a user selects an alphanumeric character based on a pronunciation of a Chinese character (e.g., Pinyin method of Chinese text enter) that the user desires to input into the electronic equipment. The candidate characters associated with the selected character are displayed in a substantially horizontal format on a display of the electronic equipment. The user is then able to select at least one candidate Chinese character that corresponds to the selected pronunciation. The candidate Chinese characters are displayed to the user in a substantially vertical format on the display above and below the selected candidate character. This cross media method of inputting Chinese characters overcomes many of the deficiencies of the prior art and allows the user to efficiently enter Chinese characters.

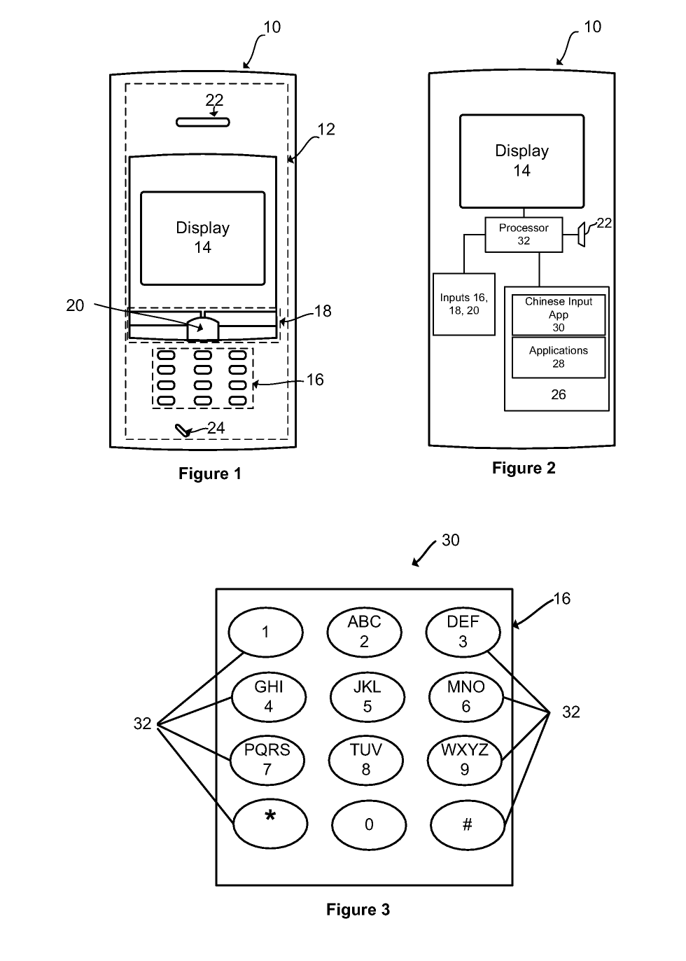

Referring to FIG. 1, electronic equipment 10 is illustrated. The electronic equipment 10 is capable of inputting Chinese characters and phrases based on symbols (e.g., alphanumeric characters, etc.) entered by an associated user. The electronic equipment 10 may include a user interface 12 that enables the user easily and efficiently to perform one or more communication tasks (e.g., enter a telephone number, identify a contact, select a contact, make a telephone call, receive a telephone call, look up a telephone number, enter a text message, receive a text message, support a plurality of languages, etc). The user interface 12 of the electronic equipment 10 generally includes one or more of the following components: a display 14, a user input device 16 (e.g., an alphanumeric keypad), function keys 18, a navigation tool 20, a speaker 22, a microphone 24 and direction arrow keys (not shown)).

As shown in FIG. 2, the electronic equipment 10 further includes one or more storage devices 26 (e.g., RAM, ROM, etc.) capable of storing one or more application programs 28 and a Chinese character input application 30, which is discussed below in detail. The storage device 26, including application programs 28 and/or Chinese character input application 30 are generally coupled to a processor 32. The processor 32 is programmed to perform the functionality described herein, for example, receiving user input information and identifying, displaying and sorting Chinese words, phrases and/or expressions based on user information input by the associated user.

The processor 32 also is coupled with conventional input devices (e.g., alphanumeric keypad 16, function keys 18, navigation tool 20 and microphone 24, etc.), and to the device display 14 and the speaker 22. The user interface 12 facilitates controlling operation of the electronic equipment 10 including initiating and conducting telephone calls and other communications (e.g., SMS communications, Internet communications, electronic mail communications, etc.).

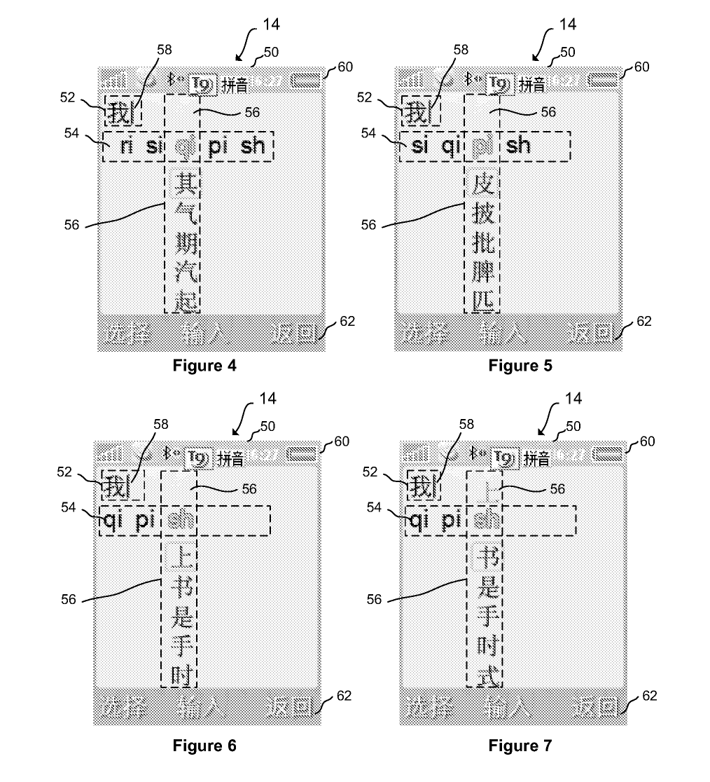

The user interface 12 is also one mechanism for the user or operator of the electronic equipment 10 to enter characters, letters, words and/or expressions for use by the Chinese character input application 30. For example, referring to FIG. 3, a user input device 16 is shown. The user input device 16 may be any input device that allows a user to enter information (e.g., symbols, alphanumeric characters, words, phrases, graphic images, text images, etc.) into the electronic equipment 10. As shown in FIG. 3, the user input device 30 is an alphanumeric keypad 16. The alphanumeric keypad 16 includes separate keys 32 for each of the numbers 0-9. The alphanumeric keypad 16 may also include keys that contain symbols (e.g. #, *, @, etc.). One of ordinary skill in the art will readily appreciate that the device display 14 may also be a user input device when properly equipped (e.g., a touch screen display).

The characters that comprise a particular alphabet may be distributed over the keys 32 of the user input device 16 (e.g., alphanumeric keypad). For example, referring to FIG. 3, the twenty-six characters that comprise the English alphabet (e.g., letters A-Z) are distributed over eight of the ten keys that comprise the numerals. The user may enter one or more characters by pressing alphanumeric keys 32. In conventional English text entry, if the user wants to enter a word, phrase and/or expression that begins with a “S”, the user would hit the “7” key four times and the letter “S” typically will be output to the display.

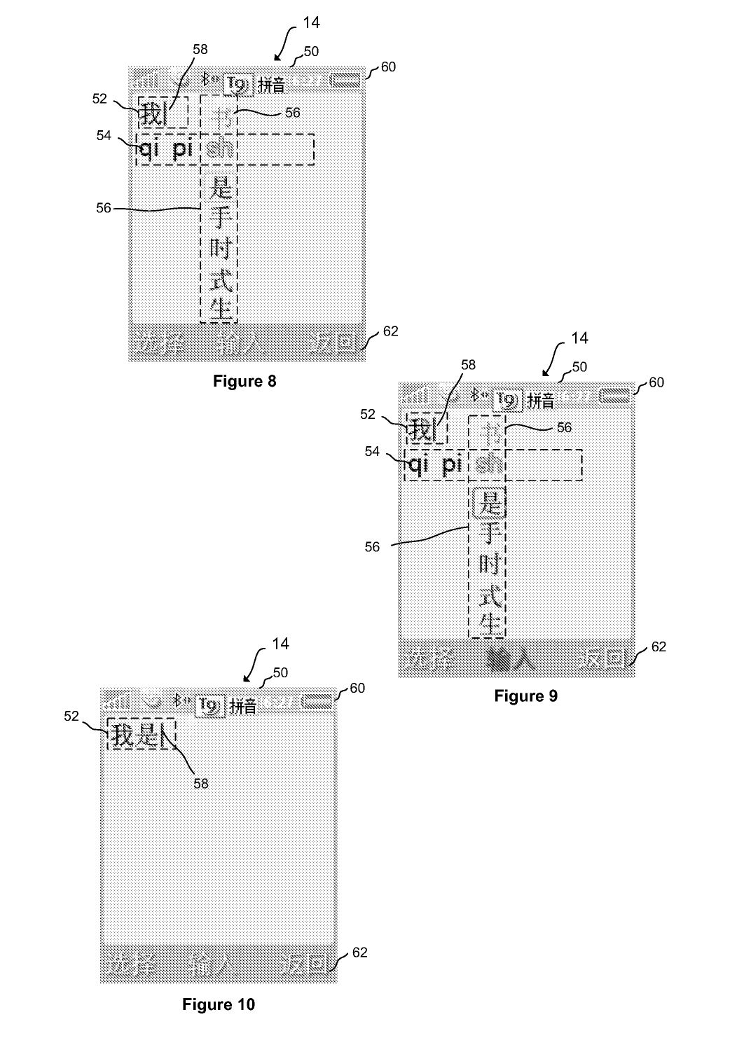

Since the Chinese input application 30 is based on the Pinyin method of text entry or another pronunciation based method of text entry, the user selects the keys 32 that correspond to the initial sound of the Chinese character desired to be entered by the user. Referring to FIG. 4, an exemplary graphical user interface 50 is shown on a display 14 of electronic equipment 10. The display 14 includes a text entry field 52, a Pinyin candidate field 54 (identified by the dashed line), a Chinese candidate field 56 (identified by the dashed line) and a cursor 58. The display 14 may also include additional information positioned along the top 60 of the display 14 and/or the bottom 62 of the display 14. As one of ordinary skill in the art will readily appreciate, the information contained in the field located along the top 60 of the display and/or the bottom 62 of the display may be any desired information. Exemplary information includes date, time, strength of communications signal, battery power status, roaming or non-roaming, etc.

FIG. 4 is an exemplary illustration of a graphical user interface in accordance with aspects of the present invention. In this example, the user desires to enter a Chinese character that is pronounced “shi”. The example shown in FIG. 4 illustrates that the user has already entered one Chinese character in the text entry field 52. The cursor 58 illustrates where the next Chinese character will be inserted. Since the next desired Chinese character to be entered is pronounced “shi”, the user presses the “7” key and the “4” key for inputting the “shi” sound. The corresponding Pinyin candidates associated with the combination of key presses for “7” and “4” are displayed to the user on the display 14. In one embodiment of the present invention, Pinyin candidates associated with a particular user input is displayed horizontally in a Pinyin candidate bar 54. As shown in FIG. 4, the Pinyin candidate bar 54 includes the following combinations of sounds “ri”, “si”, “qi”, “pi” and “sh”. As stated above, the Pinyin candidates are generated by listing possible and/or likely combinations that can be formed with the alphanumeric characters associated with the keys depressed by the user. For example, the “7” key has potential letters p, q, r, s and the “4” key has potential letters g, h, i. The resulting combination of Chinese pronunciations is displayed on the Pinyin candidate bar 54 (e.g., ri, si, qi, pi, sh). The precise order of the candidate listing may be any desired order. In one embodiment, the order of candidates is alphabetical. In another embodiment, the order is based upon a probability that at least one of the candidate characters are most likely to be selected by an associated user. One design consideration in the display order is to attempt to minimize user navigation through listing of possible candidates. In another embodiment, the candidate list may be ordered by how frequently a Chinese character is used by the particular user of the electronic equipment 10.

FIG. 4 illustrates that the Pinyin candidate currently selected by the user is “qi”. Assuming the user is in the process of inputting a Chinese character that is pronounced “shi”, the user may navigate and or otherwise traverse across the Pinyin candidate bar 54, as illustrated in FIGS. 4-6. Movement of the selected candidate may be accomplished by any means and/or mechanism. Typically, the user may select another candidate by using a suitable user input device. Suitable user input devices includes, for example, keypad 16, function keys 18, navigation tool 20, arrow keys (not shown), etc.

In one embodiment of the present invention, when the user selects a particular Pinyin candidate, the corresponding Chinese characters may be displayed to the user. As shown in the Figures, the Chinese characters corresponding to a particular Pinyin candidate are displayed vertically on the display. The precise order of the Chinese character candidates may be any desired order. In one embodiment, the order of Chinese character candidates is based upon a probability that the Chinese candidate characters are most likely to be selected by an associated user. One design consideration in the display order is to attempt to minimize user navigation through listing of possible candidates. In another embodiment, the candidate list may be ordered by how frequently a Chinese character is used by the particular user of the electronic equipment 10.

Once the user navigates to the Pinyin candidate having the correct pronunciation, as shown in FIG. 8, the user may then navigate through the one or more Chinese character candidates to the desired Chinese character. As illustrated in the FIGS. 7-10, the Chinese character candidate field 56 is displayed vertically on the display 14. The orientation of the Pinyin candidate bar 54 in one direction and the Chinese character bar 56 in a different orientation allows the user easily and efficiently to navigate among pronunciations and actual Chinese characters associated with the corresponding pronunciations.

Referring to FIGS. 7 and 8, as the user navigates toward the desired character, unwanted Chinese characters may be displayed above the Pinyin candidate bar 54, in order to illustrate the unwanted character and/or to illustrate traversal of the list by the user. An advantage of this method is that certain Pinyin candidates will have associated Chinese characters that are unable to be displayed or otherwise presented on the display 14. This is particularly true for a display on a portable communications device, such as a mobile telephone, which generally has a small display 14.

Once the user navigates to the desired Chinese character the user may insert the desired character into the text entry field 52. The user may insert or otherwise select the desired character in any manner. For example, the user may press a return (or enter key), press an insert key, use a voice command to select the desired character, select a number associated with the entry, etc. Once the user manifests his or her intent to select the desired Chinese character, the selected Chinese character will be presented on the display 14 in a user-sensible format. For example, the selected Chinese character may be inserted before or after the cursor 62. In one embodiment illustrated in FIG. 10, the selected Chinese character is inserted before the cursor 62. The cursor 62 may then advance to the next text position.

One of ordinary skill in the art will readily appreciate that although aspects of the present invention have been described with the Pinyin candidate bar 52 displayed horizontally across the display 14 and the Chinese character bar 56 being displayed vertically on the display, the Pinyin candidate bar 52 may also be displayed vertically and the Chinese character bar 56 may be displayed horizontally.

One of ordinary skill in the art will readily appreciate that the alphanumeric keys illustrated are exemplary and may be suitably modified and/or altered based on a variety of design considerations including, for example, the language of user, country of user, a particular dialect, inclusion of a QWERTY user input device or other user input device, etc.

Once the desired Chinese character is selected, the user may continue entering a message and/or phrase (or other information) and the process described above will continue for each Chinese character and/or Chinese characters entered by the user. When the user has completed entering a message and/or phrase, the user may store the message in storage element 26, may the message and/or phrase for communication purposes (e.g. short message service and electronic mail to another individual or group of individuals, Internet applications, messaging applications, etc.

An exemplary method 100 in accordance with aspects of the present invention is illustrated in FIG. 10. At step 102, an input signal is received from an input device. The input signal corresponds to one or more alphanumeric characters selected by an associated user. The input signal corresponds to a pronunciation of a Chinese character that the associated user desires to input into the electronic equipment.

At step 104, one or more candidate characters associated with the received input signal are displayed in a first format on a display. The candidate characters generally correspond to one or more combinations of pronunciations associated with the received input signal.

At step 106, the user selects at least one candidate character based at least in part on the pronunciation of a desired Chinese character to be entered into the electronic equipment.

At step 108, at least one Chinese character associated with the at least one candidate character is displayed in a second format on the display. The first and second formats are generally substantially perpendicular relative to each other. In one embodiment, the first format is substantially horizontal and the second format is substantially vertical to each other. In another embodiment, the first format is substantially vertical and the second format is substantially horizontal to each other.

Specific embodiments of an invention are disclosed herein. One of ordinary skill in the art will readily recognize that the invention may have other applications in other environments. In fact, many embodiments and implementations are possible. The following claims are in no way intended to limit the scope of the present invention to the specific embodiments described above. In addition, any recitation of “means for” is intended to evoke a means-plus-function reading of an element and a claim, whereas, any elements that do not specifically use the recitation “means for”, are not intended to be read as means-plus-function elements, even if the claim otherwise includes the word “means”. It should also be noted that although the specification lists method steps occurring in a particular order, these steps may be executed in any order, or at the same time.

Computer program elements of the invention may be embodied in hardware and/or in software (including firmware, resident software, micro-code, etc.). The invention may take the form of a computer program product, which can be embodied by a computer-usable or computer-readable storage medium having computer-usable or computer-readable program instructions, “code” or a “computer program” embodied in the medium for use by or in connection with the instruction execution system. In the context of this document, a computer-usable or computer-readable medium may be any medium that can contain, store, communicate, propagate, or transport the program for use by or in connection with tile instruction execution system, apparatus, or device. The computer-usable or computer-readable medium may be, for example but not limited to, an electronic, magnetic, optical, electromagnetic, infrared, or semiconductor system, apparatus, device, or propagation medium such as the Internet. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner. The computer program product and any software and hardware described herein form the various means for carrying out the functions of the invention in the example embodiments.

What is claimed is:

1. A method for inputting Chinese characters in electronic equipment, the method comprising:
receiving an input signal from an input device, wherein the input signal corresponds to one or more alphanumeric characters selected by an associated user, wherein the input signal corresponds to a pronunciation of a of Chinese character that the associated user desires to input into the electronic equipment;
displaying one or more candidate characters associated with the received input signal in a first format on a display, wherein the candidate characters correspond to one or more combinations of pronunciations associated with the received input signal;
selecting at least one candidate character based at least in part on the pronunciation of a desired Chinese character to be entered into the electronic equipment;
displaying at least one Chinese character associated with the at least one candidate character, wherein the at least one Chinese character is displayed in a second format on the display and the second format extends across the characters displayed in the first format.

2. The method of claim 1, wherein the first format is substantially perpendicular to the second format.

3. The method of claim 2, wherein the first format is substantially horizontal and the second format is substantially vertical.

4. The method of claim 1, wherein at least one Chinese character is displayed above the selected candidate character and at least one Chinese character is displayed below the selected candidate character.

5. The method of claim 1, wherein at least one Chinese character is displayed adjacent the selected candidate character and at least one Chinese character is displayed on an opposing side of the selected candidate character.

6. The method of claim 1, wherein the input device is an alphanumeric keypad.

7. The method of claim 1, wherein a navigation tool is used to perform the step of selecting at least one candidate character.

8. The method of claim 1 further comprising selecting at least one of the displayed Chinese characters.

9. The method of claim 8, wherein a navigation tool is used by the associated user to perform the step of selecting at least one of the displayed Chinese characters.

10. The method of claim 9, wherein the navigation tool is used by the associated user to vertically traverse a listing of Chinese characters to select the at least one Chinese character desired by the user.

11. The method of claim 1, wherein the selected Chinese character is displayed on the display as a portion of a message to be conveyed to another associated user over a telecommunications network.

12. The method of claim 1 further including displaying the one or more candidate characters to the associated user in a predetermined manner.

13. The method according to claim 12, wherein the predetermined manner is based upon a probability that at least one of the candidate characters are most likely to be selected by an associated user.

14. The method of claim 1, further including displaying the at least one Chinese character associated with the at least one candidate character in a predetermined manner.

15. The method according to claim 14, wherein the predetermined manner is based upon a probability that at least one of the candidate characters are most likely to be selected by an associated user.

16. A portable communications device comprising:
a memory;
an input device for allowing an associated user to enter user information;
a processor that executes an application program within the memory, the application program when executed causing the portable communications device to:
receive information from the input device, wherein the information corresponds a plurality of alphanumeric characters corresponding to a pronunciation of a of Chinese character that the associated user desires to input into the portable communications device;
displaying one or more candidate characters associated with the received information in a first format on a display, wherein the candidate characters correspond to one or more combinations of pronunciations associated with the received information;
selecting at least one candidate character based at least in part on the pronunciation of a desired Chinese character to be entered into the portable communications device;
displaying at least one Chinese character associated with the at least one candidate character, wherein the at least one Chinese character is displayed in a second format on the display.

17. The portable communications device of claim 14, wherein the first format is substantially perpendicular to the second format.

18. The portable communications device of claim 15, wherein the first format is substantially horizontal and the second format is substantially vertical.

19. The portable communications device of claim 16, wherein at least one Chinese character is displayed above the selected candidate character and at least one Chinese character is displayed below the selected candidate character.

20. The portable communications device of claim 16, wherein at least one Chinese character is displayed adjacent the selected candidate character and at least one Chinese character is displayed on an opposing side of the selected candidate character.

21. The portable communications device of claim 20, wherein the navigation tool is used by the associated user to vertically traverse a listing of Chinese characters to select the at least one Chinese character associated with the selected candidate character.

22. The portable communications device of claim 21, wherein the selected Chinese character is a portion of a message to be electronically conveyed to a user over a telecommunications network.

23. The portable communications device of claim 16 further including displaying the one or more candidate characters to the associated user in a predetermined manner.

24. The method according to claim 23, wherein the predetermined manner is based upon a probability that at least one of the candidate characters are most likely to be selected by an associated user.

25. A computer program stored on a machine readable medium, the program being suitable for inputting Chinese characters in electronic equipment, wherein:
when the program is loaded in memory in the electronic equipment and executed causes the electronic equipment to receive information from an input device, wherein the information corresponds a plurality of alphanumeric characters corresponding to a pronunciation of a of Chinese character that the associated user desires to input into the portable communications device;
display one or more candidate characters associated with the received information in a first format on a display, wherein the candidate characters correspond to one or more combinations of pronunciations associated with the received information;
select at least one candidate character based at least in part on the pronunciation of a desired Chinese character to be entered into the portable communications device; and
display at least one Chinese character associated with the at least one candidate character, wherein the at least one Chinese character is displayed in a second format on the display and the second format extends across the characters displayed in the first format.
